(19) United States
(12) Patent Application Publication
(10) Pub. No.: US 2023/0395760 A1
(43) Pub. Date: Dec. 7, 2023

(54) PASSIVATION STRUCTURES FOR LIGHT-EMITTING DIODE CHIPS

(71) Applicant: CreeLED, Inc., Durham, NC (US)

(72) Inventors: Michael Check, Holly Springs, NC (US); Justin White, Morrisville, NC (US); Steven Wuester, Wake Forest, NC (US); Nikolas Hall, Durham, NC (US); Kevin Haberern, Cary, NC (US); Colin Blakely, Raleigh, NC (US); Jesse Reiherzer, Raleigh, NC (US)

(21) Appl. No.: 18/302,123

(22) Filed: Apr. 18, 2023

Related U.S. Application Data
(60) Provisional application No. 63/365,644, filed on Jun. 1, 2022.

(51) Int. Cl. H01L 33/54; H01L 33/62; H01L 33/60

(52) U.S. Cl. CPC H01L 33/54; H01L 33/62; H01L 33/60

(57) ABSTRACT

Solid-state lighting devices including light-emitting diodes (LEDs) and more particularly passivation structures for LED chips are disclosed. LED chips include active LED structures, typically formed of epitaxial semiconductor layers, that include mesas with mesa sidewalls. Passivation structures include a passivation layer that bounds the mesa sidewalls. The passivation layer includes a material that is robust to etchants of active LED structures when forming the mesas to reduce damage in underlying portions of the LED chip. The passivation layer effectively forms a seal along the mesa sidewalls that reduces unwanted undercutting or erosion during etching, thereby providing improved reliability, reduced moisture ingress, and the flexibility to enable additional chip structures, such as light extraction features.

### RELATED APPLICATIONS

This application claims the benefit of provisional patent application Ser. No. 63/365,644, filed Jun. 1, 2022, the disclosure of which is hereby incorporated herein by reference in its entirety.

### FIELD OF THE DISCLOSURE

The present disclosure relates to solid-state lighting devices including light-emitting diodes (LEDs) and more particularly to passivation structures for LED chips.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

As advancements in modern LED technology progress, the art continues to seek improved LEDs and solid-state lighting devices having desirable illumination characteristics capable of overcoming challenges associated with conventional devices.

### SUMMARY

The present disclosure relates to solid-state lighting devices including light-emitting diodes (LEDs) and more particularly to passivation structures for LED chips. LED chips include active LED structures, typically formed of epitaxial semiconductor layers, that include mesas with mesa sidewalls. Passivation structures include a passivation layer that bounds the mesa sidewalls. The passivation layer includes a material that is robust to etchants of active LED structures when forming the mesas to reduce damage in underlying portions of the LED chip. The passivation layer effectively forms a seal along the mesa sidewalls that reduces unwanted undercutting or erosion during etching, thereby providing improved reliability, reduced moisture ingress, and the flexibility to enable additional chip structures, such as light extraction features.

In one aspect, an LED chip comprises: a carrier submount; an active LED structure bonded to the carrier submount, the active LED structure comprising an n-type layer, a p-type layer, and an active layer that is between the n-type layer and the p-type layer, the active LED structure forming a mesa with mesa sidewalls that define a perimeter of the active LED structure; a reflective structure between the active LED structure and the carrier submount; and a passivation layer between the reflective structure and the carrier submount, a portion of the passivation layer laterally extending past the mesa sidewalls such that the mesa sidewalls are bounded by the passivation layer. The LED chip may further comprise a barrier layer arranged between the carrier submount and the passivation layer, wherein the barrier layer is electrically coupled to the reflective structure by a number of barrier interconnects that extend through the passivation layer. The LED chip may further comprise a contact electrically coupled to the barrier layer outside the mesa sidewalls, wherein the contact extends through the passivation layer. In certain embodiments, the reflective structure comprises a dielectric layer and a metal layer on the active LED structure and the dielectric layer is arranged between the metal layer and the active LED structure, wherein the barrier interconnects are electrically coupled to the metal layer. The LED chip may further comprise reflective layer interconnects that extend from the metal layer and through the dielectric layer. In certain embodiments, the barrier interconnects are laterally offset from the reflective layer interconnects. In certain embodiments, the dielectric layer of the reflective structure extends on a portion of the n-type layer proximate the perimeter of the active LED structure; and the passivation layer laterally extends past the dielectric layer at the perimeter of the active LED structure such that the passivation layer contacts the n-type layer between the dielectric layer and the mesa sidewalls. In certain embodiments, the mesa sidewalls are formed by a portion of the n-type layer; and the passivation layer contacts a portion of the n-type layer that laterally extends past the active layer and the p-type layer proximate the mesa sidewalls. The LED chip may further comprise a top passivation layer on a portion of the active LED structure such that a portion of the n-type layer is between the top passivation layer and the carrier submount, wherein the top passivation layer further extends on the mesa sidewalls and contacts the portion of the passivation layer that laterally extends past the mesa sidewalls such that the mesa sidewalls are bounded by the top passivation layer and the passivation layer.

In another aspect, an LED chip comprises: a carrier submount; an active LED structure bonded to the carrier submount, the active LED structure comprising an n-type layer, a p-type layer, and an active layer arranged between the n-type layer and the p-type layer, the active LED structure forming a mesa with mesa sidewalls that define a perimeter of the active LED structure; and a passivation layer comprising silicon nitride, the passivation layer laterally extending past the mesa sidewalls such that the mesa sidewalls are bounded by the passivation layer. The LED chip may further comprise a top passivation layer on a portion of the active LED structure such that a portion of the n-type layer is between the top passivation layer and the carrier submount, wherein the top passivation layer further extends on the mesa sidewalls and contacts the portion of the passivation layer that laterally extends past the mesa sidewalls. In certain embodiments, the LED chip further comprises a reflective structure between the active LED structure and the carrier submount; and a barrier layer electrically coupled to the reflective structure; wherein a portion of the passivation layer is between the reflective structure and the barrier layer. In certain embodiments, the reflective structure comprises a dielectric layer and a metal layer on the active LED structure and a number of reflective layer interconnects that extend from the metal layer to form electrically conductive paths through the dielectric layer; the barrier layer is electrically coupled to the reflective structure by a number of barrier interconnects that extend through the passivation layer; and the barrier interconnects are laterally offset from the reflective layer interconnects.

In another aspect, an LED chip comprises: a carrier submount; an active LED structure bonded to the carrier submount; a reflective structure between the active LED structure and the carrier submount; a passivation layer between the reflective structure and the carrier submount; and a barrier layer arranged between the passivation layer and the carrier submount, the barrier layer being electrically coupled to the reflective structure by a number of barrier interconnects that extend through the passivation layer. In certain embodiments: the active LED structure forms a mesa with mesa sidewalls that define a perimeter of the active LED structure; and a portion of the passivation layer laterally extends past the mesa sidewalls such that the mesa sidewalls are bounded by the passivation layer. The LED package may further comprise a top passivation layer on the mesa sidewalls, wherein the top passivation layer contacts the passivation layer past the mesa sidewalls. The LED package may further comprise a contact electrically coupled to the barrier layer outside the mesa sidewalls, wherein the contact extends through the passivation layer and the top passivation layer. In certain embodiments, the reflective structure comprises a metal layer and a dielectric layer that is between the metal layer and the active LED structure and the barrier interconnects are electrically coupled to the metal layer. The LED chip may further comprise reflective layer interconnects that extend from the metal layer and through the dielectric layer. In certain embodiments, the barrier interconnects are laterally offset from the reflective layer interconnects.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a generalized cross-section of a light-emitting diode (LED) chip that embodies a vertical chip structure according to principles of the present disclosure.

FIG. 2 is a cross-section of an LED chip that is similar to the LED chip of FIG. 1 and further includes a second passivation layer that is arranged between an adhesion layer and a reflective structure formed by first and second reflective layers.

FIG. 3 is a top view of a mask that may define etch locations in the second passivation layer of FIG. 2.

FIG. 4A is a cross-section of an LED chip that is similar to the LED chip of FIG. 2 at a fabrication step after mesa sidewalls have been formed by an etching process through the active LED structure.

FIG. 4B is a cross-section of the LED chip of FIG. 4A at a subsequent fabrication step where a photoresist layer is formed along the perimeter of the active LED structure outside the mesa sidewalls.

FIG. 4C is a cross-section of the LED chip of FIG. 4B at a subsequent fabrication step where the top passivation layer is first removed or stripped, followed by removal of the photoresist layer of FIG. 4B.

FIG. 4D is a cross-section of the LED chip of FIG. 4C at a subsequent fabrication step where the exposed n-type layer is textured along the top surface.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to passivation structures for LED chips. LED chips include active LED structures, typically formed of epitaxial semiconductor layers, that include mesas with mesa sidewalls. Passivation structures include a passivation layer that bounds the mesa sidewalls. The passivation layer includes a material that is robust to etchants of active layer structures when forming the mesas to reduce damage in underlying portions of the LED chip. The passivation layer effectively forms a seal along the mesa sidewalls that reduces unwanted undercutting or erosion during etching, thereby providing improved reliability, reduced moisture ingress, and the flexibility to enable additional chip structures, such as light extraction features.

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), GaN, with a suitable substrate being a 4H polytype of SiC, although other SiC polytypes can also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light transmissive optical properties.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip can also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{i-x-y}SrₓEu_{y}AlSiN₃) and combinations thereof. One or more lumiphoric materials may be provided on one or more portions of an LED chip and/or a submount in various configurations. In certain embodiments, one or more surfaces of LED chips may be conformally coated with one or more lumiphoric materials, while other surfaces of such LED chips and/or associated submounts may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) are coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, such as vertical geometry. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described may also be applicable to flip-chip structures where anode and cathode connections are made from a same side of the LED chip for flip-chip mounting to another surface.

Aspects of the present disclosure relate to LED chip structures that adds a passivation layer, such as silicon nitride, to form a hermetic seal along a perimeter of an active LED structure mesa in a vertical chip structure. The passivation layer allows for a multitude of new processing and/or structural improvements in a vertical LED chip structure, including but not limited to: reduced undercutting or erosion of the adhesion layer, increased reworks without risk of yield loss, improved reliability, reduced risk of moisture ingress; enabling the addition of other technology to vertical LED chip structures, such as dielectric reflective structures and/or DBR reflectors; and enabling texturing to mesa edges during mesa processing. In contrast, existing vertical chip structures may employ other dielectric layers, such as oxides, along perimeters of active LED structure mesas. Such oxides, including SiO₂, are vulnerable to chemical attack when exposed along LED chip perimeters. By providing passivation layers according to the present disclosure, LED chip structures may be sealed along the perimeter to allow for more robust processing and further chip structure optimizations to improve performance.

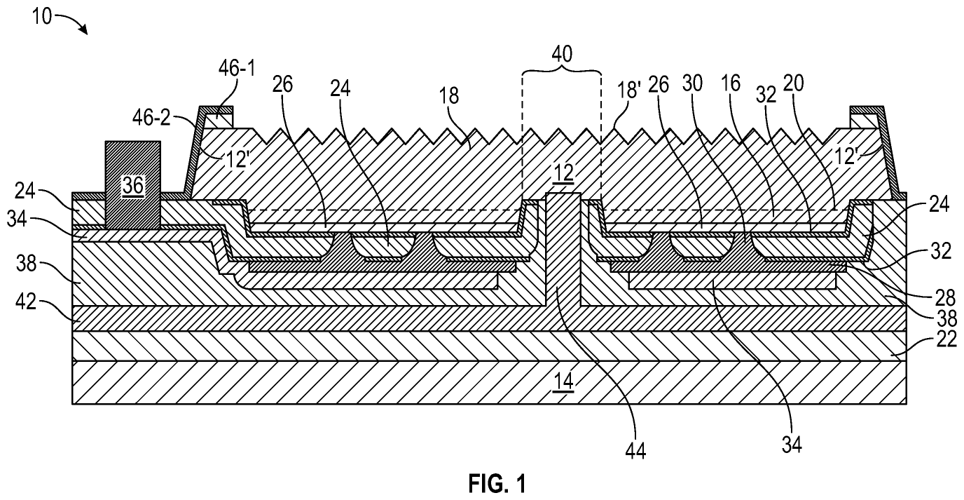

FIG. 1 is a generalized cross-section of an LED chip 10 that embodies a vertical chip structure according to principles of the present disclosure. The LED chip 10 includes an active LED structure 12 formed on a carrier submount 14. The active LED structure 12 generally refers to portions of the LED chip 10 that include semiconductor layers, such as epitaxial semiconductor layers, that form a structure that generates light when electrically activated. The active LED structure 12 is formed on and supported by the carrier submount 14 that can be made of many different materials, with a suitable material being silicon, or doped silicon. In certain embodiments, the carrier submount 14 comprises an electrically conductive material such that the carrier submount 14 is part of electrically conductive connections to the active LED structure 12. The active LED structure 12 may generally comprise a p-type layer 16, an n-type layer 18, and an active layer 20 arranged between the p-type layer 16 and the n-type layer 18. The active LED structure 12 may include many additional layers such as, but not limited to, buffer layers, nucleation layers, super lattice structures, un-doped layers, cladding layers, contact layers, current-spreading layers, and light extraction layers and elements. Additionally, the active layer 20 may comprise a single quantum well, a multiple quantum well, a double heterostructure, or super lattice structures. In FIG. 1, the p-type layer 16 is arranged between the active layer 20 and the carrier submount 14 such that the p-type layer 16 is closer to the carrier submount 14 than the n-type layer 18. The active LED structure 12 may initially be formed by epitaxially growing or depositing the n-type layer 18, the active layer 20, and the p-type layer 16 sequentially on a growth substrate. The active LED structure 12 may then be flipped and bonded to the carrier submount 14 by way of one or more bond metals 22 and the growth substrate is removed. In this manner, a top surface 18′ of the n-type layer 18 forms a primary light extracting face of the LED chip 10. In certain embodiments, the top surface 18′ may comprise a textured or patterned surface for improving light extraction. In other embodiments, the doping order may be reversed such that the n-type layer 18 is arranged between the active layer 20 and the carrier submount 14.

The LED chip 10 may include a first reflective layer 24 provided on the p-type layer 16. In certain embodiments, a current spreading layer 26 may be provided between the p-type layer 16 and the first reflective layer 24. The current spreading layer 26 may include a thin layer of a transparent conductive oxide such as indium tin oxide (ITO) or a thin metal layer such as Pt, although other materials may be used. The first reflective layer 24 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the first reflective layer 24 comprises a material with an index of refraction lower than the index of refraction of the active LED structure 12 material. The first reflective layer 24 may comprise many different materials, with some having an index of refraction less than 2.3, while others can have an index of refraction less than 2.15, less than 2.0, and less than 1.5. In certain embodiments, the first reflective layer 24 comprises a dielectric material, such as silicon dioxide (SiO₂) and/or silicon nitride (SiN). It is understood that many dielectric materials can be used such as SiN, SiNₓ, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof. In certain embodiments, the first reflective layer 24 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, and SiO₂ can have an index of refraction of approximately 1.48, and SiN can have an index of refraction of approximately 1.9. Embodiments with the active LED structure 12 comprising GaN and the first reflective layer 24 comprising SiO₂ may form a sufficient index of refraction step between the two to allow for efficient TIR of light. The first reflective layer 24 may have different thicknesses depending on the type of materials used, with some embodiments having a thickness of at least 0.2 microns (μm). In some embodiments, the first reflective layer 24 can have a thickness in the range of 0.2 μm to 0.7 μm, while in some embodiments the thickness can be approximately 0.5 μm.

The LED chip 10 may further include a second reflective layer 28 that is on the first reflective layer 24 such that the first reflective layer 24 is arranged between the active LED structure 12 and the second reflective layer 28. The second reflective layer 28 may include a metal layer that is configured to reflect light from the active LED structure 12 that may pass through the first reflective layer 24. The second reflective layer 28 may comprise many different materials such as Ag, gold (Au), Al, nickel (Ni), titanium (Ti) or combinations thereof. The second reflective layer 28 may have different thicknesses depending on the type of materials used, with some embodiments having a thickness of at least 0.1 μm, or in a range including 0.1 μm to 0.7 μm, or in a range including 0.1 um to 0.5 um, or in a range including 0.1 μm to 0.3 μm. As illustrated, the second reflective layer 28 may include or form one or more reflective layer interconnects 30 that provide an electrically conductive path through the first reflective layer 24. In this manner, the one or more reflective layer interconnects 30 may extend through an entire thickness of the first reflective layer 24. In certain embodiments, the second reflective layer 28 is a metal reflective layer and the reflective layer interconnects 30 comprise reflective layer metal vias. Accordingly, the first reflective layer 24, the second reflective layer 28, and the reflective layer interconnects 30 form a reflective structure of the LED chip 10 that is on the p-type layer 16. As such, the reflective structure may comprise a dielectric reflective layer and a metal reflective layer as disclosed herein. In certain embodiments, the reflective layer interconnects 30 comprise the same material as the second reflective layer 28 and are formed at the same time as the second reflective layer 28. In other embodiments, the reflective layer interconnects 30 may comprise a different material than the second reflective layer 28. Certain embodiments may also comprise an adhesion layer 32 that is positioned at one or more interfaces between the first reflective layer 24 and the second reflective layer 28 and/or interfaces between the first reflective layer 24 and the current spreading layer 26 to promote improved adhesion therebetween. Many different materials can be used for the adhesion layer 32, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlₓO_{y}. In certain embodiments, the adhesion layer comprises AlₓO_{y}, where 1≤x≤4 and 1≤y≤6. In certain embodiments, the adhesion layer comprises AlₓO_{y}, where x=2 and y=3, or Al₂O₃. The adhesion layer 32 may be deposited by electron beam deposition that may provide a smooth, dense, and continuous layer without notable variations in surface morphology. The adhesion layer 32 may also be deposited by sputtering, chemical vapor deposition, plasma enhanced chemical vapor deposition, or atomic layer deposition (ALD).

The LED chip 10 may also comprise a barrier layer 34 on the second reflective layer 28 to prevent migration of material of the second reflective layer 28, such as Ag, to other layers. Preventing this migration helps the LED chip 10 maintain efficient operation throughout its lifetime. The barrier layer 34 may comprise an electrically conductive material, with suitable materials including but not limited Ti, Pt, Ni, Au, tungsten (W), and combinations or alloys thereof. In certain embodiments, the barrier layer 34 is arranged to laterally extend beyond portions of the active LED structure 12, or a peripheral border of the active LED structure 12 in order to provide an electrical connection with a p-contact 36. In this regard, an electrical path between the p-contact 36 and the p-type layer 16 may include the barrier layer 34, the second reflective layer 28, and the reflective layer interconnects 30. In other embodiments, the polarity may be reversed such that the p-contact 36 is replaced with an n-contact that is electrically coupled to the n-type layer 18 and electrical connections to the p-type layer 16 are made through the carrier submount 14. A passivation layer 38 is included on the barrier layer 34 as well as any portions of the second reflective layer 28 that may be uncovered by the barrier layer 34. The passivation layer 38 protects and provides electrical insulation for the LED chip 10 and can comprise many different materials, such as a dielectric material including but not limited to silicon nitride. In certain embodiments, the passivation layer 38 is a single layer, and in other embodiments, the passivation layer 38 comprises a plurality of layers. In certain embodiments, the passivation layer 38 may include one or more metal-containing interlayers arranged or embedded therein that may function as a crack stop layer for any cracks that may propagate through the passivation layer 38 as well as an additional light reflective layer.

In FIG. 1, the active LED structure 12 forms a first opening 40 or recess that extends through the p-type layer 16, the active layer 20, and a portion of the n-type layer 18. The first opening 40 may be formed by a subtractive material process, such as etching, that is applied to the active LED structure 12 before bonding with the carrier submount 14. As used herein, the first opening 40 may also be referred to as an active LED structure opening. As illustrated, a portion of the first reflective layer 24, and adhesion layer 32, is arranged to cover sidewall surfaces of the p-type layer 16, the active layer 20, and the n-type layer 18 within the first opening 40. The passivation layer 38 extends along the first reflective layer 24 in the first opening 40 and is arranged on a surface of the n-type layer 18. The LED chip 10 further includes an n-contact metal layer 42 that is arranged on the passivation layer 38 and across the LED chip 10. At the first opening 40, the n-contact metal layer 42 extends into the first opening 40 to form an n-contact interconnect 44, which may be referred to as an n-contact via. In this manner, the first opening 40 may be defined where portions of the n-contact metal layer 42, the n-contact interconnect 44, the passivation layer 38, and the first reflective layer 24 extend into the active LED structure 12. As such, the n-contact metal layer 42 and the n-contact interconnect 44 may be integrally formed to provide an electrical connection to the n-type layer 18 through the first opening 40. In other embodiments, the n-contact metal layer 42 and the n-contact interconnect 44 may be separately formed and may comprise the same or different materials. In certain embodiments, the n-contact metal layer 42 and the n-contact interconnect 44 comprise a single layer or a plurality of layers that include conductive metals, such as one or more of Al, Ti, and alloys thereof.

As illustrated, the p-contact 36 may be formed on the barrier layer 34, and one or more top passivation layers 46-1, 46-2 may be provided on one or more top or side surfaces of the n-type layer 18 for additional electrical insulation. In FIG. 1, the top passivation layer 46-2 is arranged to cover mesa sidewalls 12′ of the active LED structure 12. The top passivation layers 46-1, 46-2 may comprise separate layers of a continuous layer of dielectric material, such as silicon nitride. During fabrication of the mesa for the active LED structure 12, an etching step is applied to the active LED structure 12 from the n-type layer 18. The etching step effectively forms the mesa sidewalls 12′ with sloped surfaces along the perimeter of the active LED structure 12. However, etchants may follow boundaries of the first reflective layer 24, the adhesion layer 32, and the barrier layer 34 outside the mesa sidewalls 12′. In such instances, integrity of such layers may be compromised due to undercutting and/or erosion from the etchant, thereby leading to increased risk of moisture ingress, performance degradation, and/or reduced chip reliability.

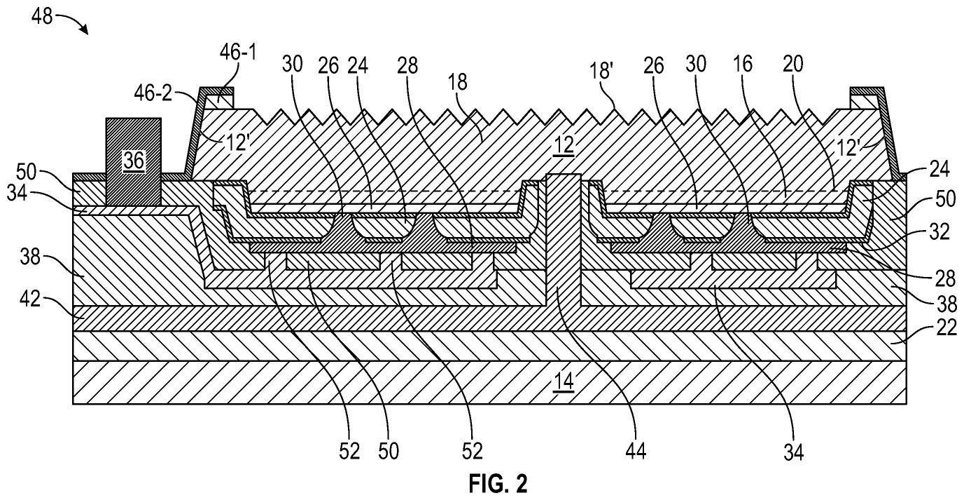

FIG. 2 is a cross-section of an LED chip 48 that is similar to the LED chip 10 of FIG. 1 and further includes a second passivation layer 50 that is arranged between the adhesion layer 32 and the reflective structure formed by the first and second reflective layers 24, 28. The passivation layer 38 as described for FIG. 1 may hereinafter be referred to as a first passivation layer 38. The second passivation layer 50 comprises a material that is more robust to etchants used to form the mesa sidewalls 12′ than the material of the first reflective layer 24 and the adhesion layer 32. In certain embodiments, the second passivation layer 50 comprises a same material as the first passivation layer 38, such as SiN. In other embodiments, the second passivation layer 50 may embody any dielectric material that is different from and is more robust to the etchants than the first reflective layer 24. In a specific example, the first reflective layer 24 comprise SiO₂ and the second passivation layer 50 comprises SiN, SiNₓ, or Si₃N₄.

As illustrated in FIG. 2, the second passivation layer 50 is arranged between the barrier layer 34 and the second reflective layer 28. In order to provide electrical connections between the barrier layer 34 and the second reflective layer 28, a number of barrier interconnects 52 are arranged through the second passivation layer 50. In certain embodiments, the location of the barrier interconnects 52 is arranged in a laterally offset manner with respect to the reflective layer interconnects 30. In this regard, a vertical line through any portion of the barrier interconnects 52 may not intersect with the reflective layer interconnects 30. Such an arrangement may avoid etchants used on the second passivation layer 50 that provide openings for the barrier interconnects 52 from reaching the previously etched regions of the first reflective layer 24 for the reflective layer interconnects 30. If the barrier interconnects 52 were aligned with the reflective layer interconnects 30, etchants for the second passivation layer 50 may also pass through the etched regions for the reflective layer interconnects 30 and possibly reach and damage portions of the active LED structure 12.

The second passivation layer 50 is also arranged between the barrier layer 34 and the first reflective layer 24 along portions of the first reflective layer 24 that are outside the second reflective layer 28. In particular, the second passivation layer 50 segregates the adhesion layer 32 and the first reflective layer 24 from the barrier layer 34 at the mesa sidewalls 12′. In this regard, the first reflective layer 24 and adhesion layer 32 may not laterally extend to the mesa sidewalls 12′. Rather, portions of the more robust second passivation layer 50 extend along portions of the n-type layer 18 and past the mesa sidewalls 12′ to bound the mesa sidewalls 12′ in a direction toward the carrier submount 14. In this manner, the second passivation layer 50 effectively seals both the first reflective layer 24 and the barrier layer 34 outside the mesa sidewalls 12′. In certain embodiments, the second passivation layer 50 forms a hermetic seal for portions of the LED chip 48 that are outside the mesa sidewalls 12′. During fabrication, the second passivation layer 50 is formed before the mesa sidewalls 12′. Accordingly, the etchants that form the mesa sidewalls 12′ may stop at the second passivation layer 50 with reduced damage to the first reflective layer 24, the adhesion layer 32, and/or the barrier layer 34. As further illustrated in FIG. 2, the p-contact 36 may be arranged to extend through the second passivation layer 50 to electrically connect with the barrier layer 34. Additionally, the top passivation layer 46-2 may cover the mesa sidewalls 12′ and portions of the second passivation layer 50 that are adjacent the p-contact 36 such that the mesa sidewalls 12′ are bounded by the top passivation layer 46-2 and the second passivation layer 50.

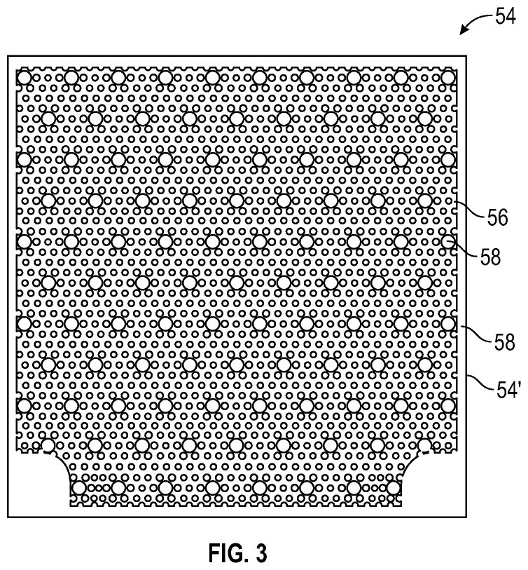

FIG. 3 is a top view of a mask 54 that may define etch locations in the second passivation layer 50 of FIG. 2. As described above for FIG. 2, openings in the second passivation layer 50 are etched to form locations for the barrier interconnects 52 that are offset with respect to the reflective layer interconnects 30. Such openings in the second passivation layer 50 may also be arranged to avoid locations of the n-contact interconnects 44 of FIG. 2. In this manner, the second passivation layer 50 may be substantially patterned by etching in certain embodiments to avoid the reflective layer interconnects 30 and/or the n-contact interconnects 44. In FIG. 3, the mask 54 is sized to cover an entire LED chip such that perimeter edges 54′ of the mask 54 correspond with perimeter edges of the LED chip. The mask 54 includes a dark pattern 56 that reflects areas where the second passivation layer 50 of FIG. 2 will be etched and subsequently removed. Accordingly, a white pattern 58 corresponds with areas where the second passivation layer 50 of FIG. 2 will remain. As illustrated, the dark pattern 56 is absent along the perimeter 54′ so that the second passivation layer 50 may form a perimeter seal, such as a hermetic seal, outside the mesa sidewalls 12′ as described above for FIG. 2.

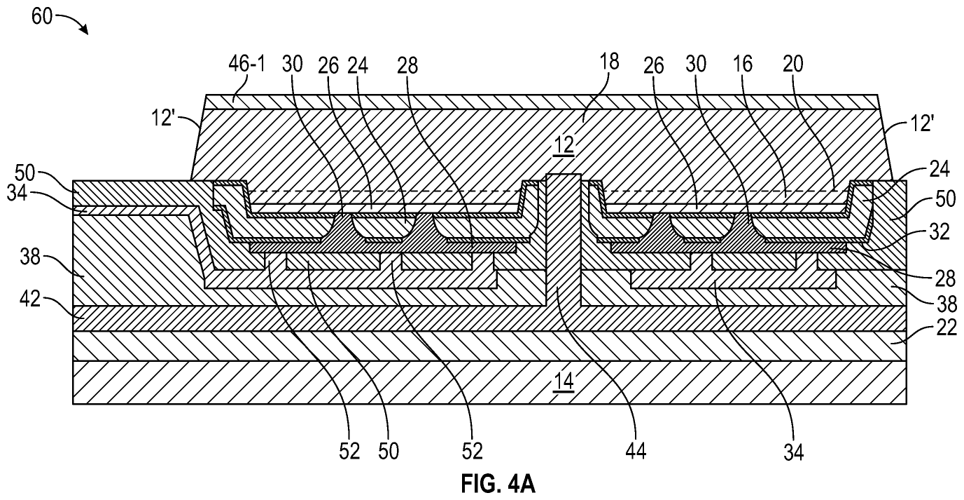

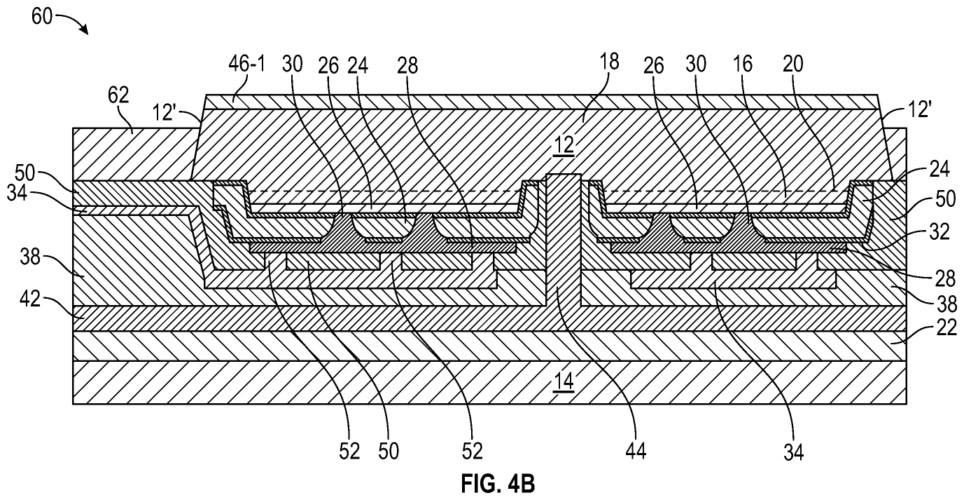

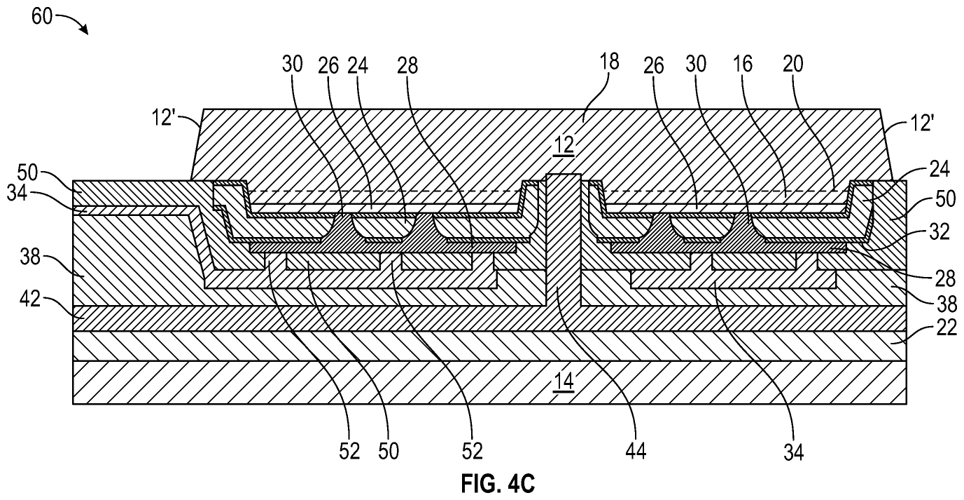

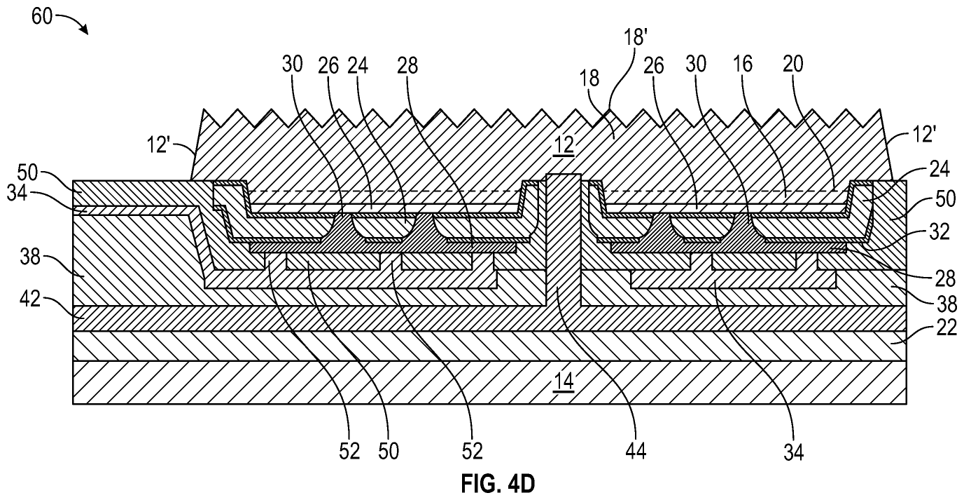

FIGS. 4A to 4D are cross-sections at various fabrication steps for an LED chip 60 that is similar to the LED chip 48 of FIG. 2 and includes additional chip features made possible by the presence of the second passivation layer 50 outside the mesa sidewalls 12′.

FIG. 4A is a cross-section of the LED chip 60 at a fabrication step after the mesa sidewalls 12′ have been formed by an etching process through the active LED structure 12. In certain embodiments, the etching process may employ a gallium phosphide (GaP) etchant. As illustrated, the mesa sidewalls 12′ are formed in a sloped manner and reach the second passivation layer 50 around a perimeter of the active LED structure 12. As previously described, the second passivation layer 50 provides a seal in such locations to reduce interaction between the etchant and other portions of the LED chip 60.

FIG. 4B is a cross-section of the LED chip 60 of FIG. 4A at a subsequent fabrication step where a photoresist layer 62 is formed along the perimeter of the active LED structure 12 outside the mesa sidewalls 12′. The photoresist layer 62 may initially be blanket deposited over the entire LED chip 60, before being removed above top portions of the active LED structure 12. In this regard, the top passivation layer 46-1 may be exposed while the second passivation layer 50 is covered by the photoresist layer 62.

FIG. 4C is a cross-section of the LED chip 60 of FIG. 4B at a subsequent fabrication step where the top passivation layer 46-1 is first removed or stripped, followed by removal of the photoresist layer 62 of FIG. 4B. In this regard, the n-type layer 18 is exposed along with the second passivation layer 50 in locations outside the mesa sidewalls 12′.

FIG. 4D is a cross-section of the LED chip 60 of FIG. 4C at a subsequent fabrication step where the exposed n-type layer 18 is textured along the top surface 18′. The texturing process may be performed by another etching step with an etchant that does not substantially damage the second passivation layer 50. Accordingly, the entire exposed top surface 18′ may be textured or otherwise patterned for enhanced light extraction. In contrast, the LED chip 10 of FIG. 1 includes portions of the n-type layer 18 that remain covered by the top passivation layers 46-1, 46-2 such that only portions of the top surface 18′ are textured. In FIG. 4D, the presence of the second passivation layer 50 outside the mesa sidewalls 12′ provides enhanced protection so that the entire top surface 18′ may be textured. In further embodiments, the etching of the mesa sidewalls 12′ at this fabrication step may further form a textured surface of the mesa sidewalls 12′ for further light extraction improvement. After all potentially harmful etching is complete, final dielectric layers, such as SiO₂ or atomic layer deposition of aluminum oxide (Al₂O₃) may be blanket deposited on the LED chip 60.

As described above, the principles of the present disclosure provide LED chip structures that serve to reduce peeling of layers outside mesa sidewalls and near contact pads. Other benefits include the ability to rework reflective structure (e.g., mirror) photo multiple times and barrier photo an infinite amount of times. The presence of the second passivation layer as described above provides a same interface between the second passivation layer and the active LED structure in the regions near topside contact pads and along chip perimeters. In this manner, other dielectric materials, such as oxides, that are more vulnerable to various etching, such as GaP etching, may be sealed and/or removed in such regions. By removing such dielectric materials from areas that are exposed to certain etching steps, the etch times may be increased without fear of over-etching that could impact mechanical integrity of underlying layers and case severe yield fallout.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
a carrier submount;
an active LED structure on the carrier submount, the active LED structure comprising an n-type layer, a p-type layer, and an active layer that is between the n-type layer and the p-type layer, the active LED structure forming a mesa with mesa sidewalls that define a perimeter of the active LED structure;
a reflective structure between the active LED structure and the carrier submount; and
a passivation layer between the reflective structure and the carrier submount, a portion of the passivation layer laterally extending past the mesa sidewalls such that the mesa sidewalls are bounded by the passivation layer.

2. The LED chip of claim 1, further comprising a barrier layer arranged between the carrier submount and the passivation layer, wherein the barrier layer is electrically coupled to the reflective structure by a number of barrier interconnects that extend through the passivation layer.

3. The LED chip of claim 2, further comprising a contact electrically coupled to the barrier layer outside the mesa sidewalls, wherein the contact extends through the passivation layer.

4. The LED chip of claim 2, wherein the reflective structure comprises a dielectric layer and a metal layer on the active LED structure and the dielectric layer is arranged between the metal layer and the active LED structure, wherein the barrier interconnects are electrically coupled to the metal layer.

5. The LED chip of claim 4, further comprising reflective layer interconnects that extend from the metal layer and through the dielectric layer.

6. The LED chip of claim 5, wherein the barrier interconnects are laterally offset from the reflective layer interconnects.

7. The LED chip of claim 2, wherein:
the dielectric layer of the reflective structure extends on a portion of the n-type layer proximate the perimeter of the active LED structure; and
the passivation layer laterally extends past the dielectric layer at the perimeter of the active LED structure such that the passivation layer contacts the n-type layer between the dielectric layer and the mesa sidewalls.

8. The LED chip of claim 1, wherein:
the mesa sidewalls are formed by a portion of the n-type layer; and
the passivation layer contacts a portion of the n-type layer that laterally extends past the active layer and the p-type layer proximate the mesa sidewalls.

9. The LED chip of claim 8, further comprising a top passivation layer on a portion of the active LED structure such that a portion of the n-type layer is between the top passivation layer and the carrier submount, wherein the top passivation layer further extends on the mesa sidewalls and contacts the portion of the passivation layer that laterally extends past the mesa sidewalls such that the mesa sidewalls are bounded by the top passivation layer and the passivation layer.

10. A light-emitting diode (LED) chip, comprising:
a carrier submount;
an active LED structure on the carrier submount, the active LED structure comprising an n-type layer, a p-type layer, and an active layer arranged between the n-type layer and the p-type layer, the active LED structure forming a mesa with mesa sidewalls that define a perimeter of the active LED structure; and
a passivation layer comprising silicon nitride, the passivation layer laterally extending past the mesa sidewalls such that the mesa sidewalls are bounded by the passivation layer.

11. The LED chip of claim 10, further comprising a top passivation layer on a portion of the active LED structure such that a portion of the n-type layer is between the top passivation layer and the carrier submount, wherein the top passivation layer further extends on the mesa sidewalls and contacts the portion of the passivation that laterally extends past the mesa sidewalls.

12. The LED chip of claim 10, further comprising:
a reflective structure between the active LED structure and the carrier submount; and
a barrier layer electrically coupled to the reflective structure;
wherein a portion of the passivation layer is between the reflective structure and the barrier layer.

13. The LED chip of claim 12, wherein:
the reflective structure comprises a dielectric layer and a metal layer on the active LED structure and a number of reflective layer interconnects that extend from the metal layer to form electrically conductive paths through the dielectric layer;
the barrier layer is electrically coupled to the reflective structure by a number of barrier interconnects that extend through the passivation layer; and
the barrier interconnects are laterally offset from the reflective layer interconnects.

14. A light-emitting diode (LED) chip, comprising:
a carrier submount;
an active LED structure on the carrier submount;
a reflective structure between the active LED structure and the carrier submount;
a passivation layer between the reflective structure and the carrier submount; and
a barrier layer arranged between the passivation layer and the carrier submount, the barrier layer being electrically coupled to the reflective structure by a number of barrier interconnects that extend through the passivation layer.

15. The LED chip of claim 14, wherein:
the active LED structure forms a mesa with mesa sidewalls that define a perimeter of the active LED structure; and
a portion of the passivation layer laterally extends past the mesa sidewalls.

16. The LED chip of claim 15, further comprising a top passivation layer on the mesa sidewalls, wherein the top passivation layer contacts the passivation layer past the mesa sidewalls.

17. The LED chip of claim 16, further comprising a contact electrically coupled to the barrier layer outside the mesa sidewalls, wherein the contact extends through the passivation layer and the top passivation layer.

18. The LED chip of claim 14, wherein the reflective structure comprises a metal layer and a dielectric layer that is between the metal layer and the active LED structure, and the barrier interconnects are electrically coupled to the metal layer.

19. The LED chip of claim 18, further comprising reflective layer interconnects that extend from the metal layer and through the dielectric layer.

20. The LED chip of claim 19, wherein the barrier interconnects are laterally offset from the reflective layer interconnects.
